(19) United States
(12) Patent Application Publication
(10) Pub. No.: US 2023/0389377 A1
(43) Pub. Date: Nov. 30, 2023

(54) DISPLAY DEVICE

(71) Applicant: Samsung Display Co., LTD., Yongin-si (KR)

(72) Inventors: Jae Ill KIM, Yongin-si (KR); Ji Hyun KIM, Yongin-si (KR); Byoung Haw PARK, Yongin-si (KR); Dae Hwan JANG, Yongin-si (KR); Eui Myeong CHO, Yongin-si (KR)

(73) Assignee: Samsung Display Co., LTD., Yongin-si (KR)

(21) Appl. No.: 18/104,888

(22) Filed: Feb. 2, 2023

(30) Foreign Application Priority Data
May 30, 2022 (KR) 10-2022-0066345

(51) Int. Cl. H10K 59/131; H10K 59/80; H10K 59/121

(52) U.S. Cl. CPC H10K 59/131; H10K 59/873; H10K 59/1213

(57) ABSTRACT

A display device includes a base layer including a first surface and a second surface, a first line disposed on the first surface of the base layer, a second line corresponding to the first line and disposed on the second surface of the base layer, and a connection film electrically contacting at least a portion of the second line and electrically connected to a printed circuit board and a driving circuit. The driving circuit is disposed between the printed circuit board and the connection film.

### CROSS-REFERENCE TO RELATED APPLICATION(S)

This application claims priority to and benefits of Korean patent application number 10-2022-0066345 under 35 U.S.C. § 119, filed on May 30, 2022, in the Korean Intellectual Property Office (KIPO), the entire contents of which are incorporated herein by reference.

### BACKGROUND

### 1. Technical Field

Various embodiments of the disclosure relate to a display device.

### 2. Description of Related Art

With an increase in interest in an information display and an increase in demand to use portable information media, demand for display devices is markedly increased, and commercialization thereof is in progress.

### SUMMARY

Various embodiments of the disclosure are directed to a display device capable of enhancing the reliability of a light emitting element included in a pixel.

A display device in accordance with an embodiment of the disclosure may include a base layer including a first surface and a second surface, a first line disposed on the first surface of the base layer, a second line corresponding to the first line and disposed on the second surface of the base layer, and a connection film electrically contacting at least a portion of the second line and electrically connected to a printed circuit board and a driving circuit. The driving circuit may be disposed between the printed circuit board and the connection film.

In an embodiment, the printed circuit board and the connection film may electrically contact each other on a first point between a second point corresponding to a first end of the printed circuit board and a third point corresponding to a second end of the printed circuit board.

In an embodiment, the printed circuit board and the connection film may be electrically connected to each other by a bonding pad including a pad electrode.

In an embodiment, the driving circuit may be located at the second point.

In an embodiment, the driving circuit may at least partially overlap the printed circuit board in a plan view.

In an embodiment, the printed circuit board may include a depression formed by etching at least a portion of the printed circuit board.

In an embodiment, the driving circuit may be disposed in the depression of the printed circuit board.

In an embodiment, the depression of the printed circuit board may be located at the second point.

In an embodiment, the driving circuit may at least partially overlap the depression of the printed circuit board in a plan view.

In an embodiment, the display device may further include a first protective layer disposed on an entire surface of the second surface including the second line and including an area exposing at least a portion of the second line.

In an embodiment, the display device may further include a second protective layer disposed on a lower surface of the first protective layer to cover at least a portion of the first protective layer.

In an embodiment, the second protective layer and the printed circuit board may be disposed on a same layer.

In an embodiment, the second protective layer may be disposed between the first protective layer and the printed circuit board.

In an embodiment, the second protective layer may include graphite.

In an embodiment, the display device may further include a pixel circuit layer disposed on the first surface of the base layer and including the first line, a display element layer disposed on the pixel circuit layer and including a display element, and a thin-film encapsulation layer disposed on the display element layer.

In an embodiment, the display device may further include a light conversion layer disposed between the display element layer and the thin-film encapsulation layer.

In an embodiment, the pixel circuit layer may include at least one transistor and a plurality of insulating layers. The at least one transistor may include a semiconductor pattern disposed on the first surface of the base layer and including a channel area, a source area, and a drain area, a gate electrode disposed to overlap the channel area in a plan view, and a source electrode and a drain electrode respectively electrically connected to the source area and the drain area. The plurality of insulating layer may include a gate insulating layer disposed between the semiconductor pattern and the gate electrode, and an interlayer insulating layer disposed on the gate electrode.

In an embodiment, the first line may include at least one of a first gate line and a first data line. The second line may include at least one of a second gate line electrically connected to the first gate line through a base hole passing through the base layer and a second data line electrically connected to the first data line through the base hole. The first gate line and the gate electrode may be disposed on a same layer. The first data line and at least one of the source electrode and the drain electrode may be disposed on a same layer.

In an embodiment, the base hole may be filled with a conductive material, and the first line and the second line may be electrically connected to each other by the conductive material.

A display device in accordance with an embodiment of the disclosure may include a base layer including a first surface and a second surface, a first line disposed on the first surface of the base layer, a second line corresponding to the first line and disposed on the second surface of the base layer, and a connection film electrically contacting at least a portion of the second line and electrically connected to a printed circuit board and a driving circuit. The driving circuit may at least partially overlap the printed circuit board in a plan view.

### BRIEF DESCRIPTION OF THE DRAWINGS

FIG. 1 is a perspective view illustrating a display device in accordance with an embodiment of the disclosure.

FIGS. 2A and 2B are schematic cross-sectional views each illustrating a display device in accordance with an embodiment of the disclosure.

FIGS. 3A and 3B are schematic cross-sectional views each illustrating a display panel in accordance with an embodiment of the disclosure.

FIG. 4 is a perspective view illustrating a multi-screen display device in accordance with an embodiment of the disclosure.

FIGS. 5A and 5B are plan views each illustrating a multi-screen display device in accordance with an embodiment of the disclosure.

FIG. 6 is a schematic diagram illustrating a display device in accordance with an embodiment of the disclosure.

FIG. 7 is a plan view schematically illustrating a display panel in accordance with an embodiment of the disclosure.

FIGS. 8A to 8C are schematic diagrams of an equivalent circuit of a pixel included in the display device of FIG. 7.

FIGS. 9A to 9C are schematic cross-sectional views each illustrating a display panel in accordance with an embodiment of the disclosure.

FIG. 10A is a schematic partial cross-sectional view of the display device in accordance with an embodiment of the disclosure.

FIG. 10B is a plan view for describing an arrangement of a connection film, a driving circuit, and a printed circuit board that are included in the display device of FIG. 10A in accordance with an embodiment of the disclosure.

FIG. 11A is a schematic partial cross-sectional view of the display device in accordance with an embodiment of the disclosure.

FIG. 11B is a schematic partial cross-sectional view of the display device in accordance with an embodiment of the disclosure.

FIG. 11C is a plan view for describing an arrangement of a connection film, a driving circuit, and a printed circuit board that are included in the display device of FIG. 11A in accordance with an embodiment of the disclosure.

FIG. 12 is a schematic partial cross-sectional view of the display device in accordance with an embodiment of the disclosure.

FIG. 13 is a schematic partial cross-sectional view of the display device in accordance with an embodiment of the disclosure.

### DETAILED DESCRIPTION OF THE EMBODIMENTS

Throughout the disclosure, like reference numerals refer to like parts throughout the various figures and embodiments of the disclosure. The sizes of elements in the accompanying drawings may be exaggerated for clarity of illustration. Although the terms “first”, “second”, etc. may be used herein to describe various types of elements, these elements should not be limited by these terms. These terms are used to distinguish one element from another element. Thus, a first element discussed below could be termed a second element without departing from the teachings of the disclosure. In the disclosure, the singular forms are intended to include the plural forms as well, unless the context clearly indicates otherwise.

It will be understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof.

When an element, such as a layer, is referred to as being “on”, “connected to”, or “coupled to” another element or layer, it may be directly on, connected to, or coupled to the other element or layer or intervening elements or layers may be present. When, however, an element or layer is referred to as being “directly on”, “directly connected to”, or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Furthermore, in case that a first part such as a layer, a film, a region, or a plate is disposed on a second part, the first part may be not only directly on the second part, but a third part may intervene between them. In case that it is expressed that a first part such as a layer, a film, a region, or a plate is formed on a second part, the surface of the second part on which the first part is formed is not limited to an upper surface of the second part but may include other surfaces such as a side surface or a lower surface of the second part. To the contrary, in case that a first part such as a layer, a film, a region, or a plate is under a second part, the first part may be not only directly under the second part, but a third part may intervene between them.

In the specification and the claims, the phrase “at least one of” is intended to include the meaning of “at least one selected from the group of” for the purpose of its meaning and interpretation. For example, “at least one of A and B” may be understood to mean “A, B, or A and B.”

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Various embodiments of the disclosure will hereinafter be described in detail with reference to the accompanying drawings. The same reference numerals are used throughout the different drawings to designate the same components, and repetitive description of the same components will be omitted.

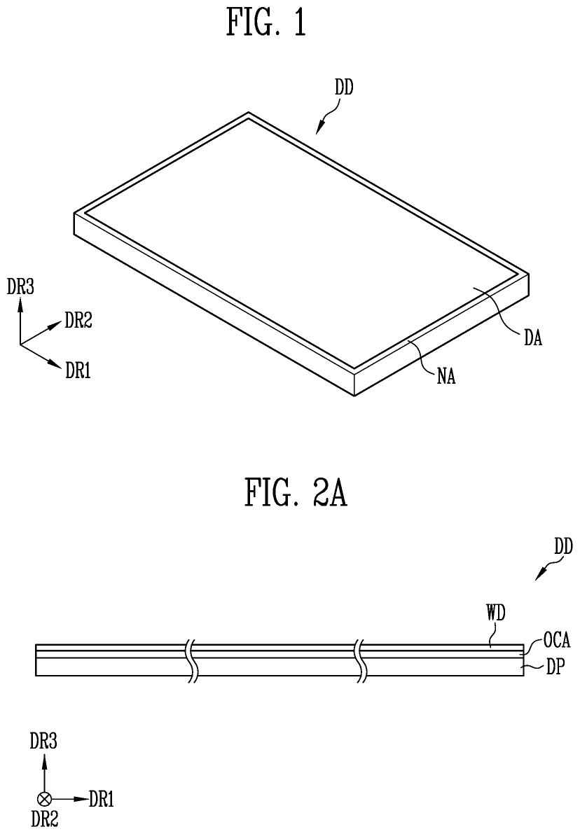

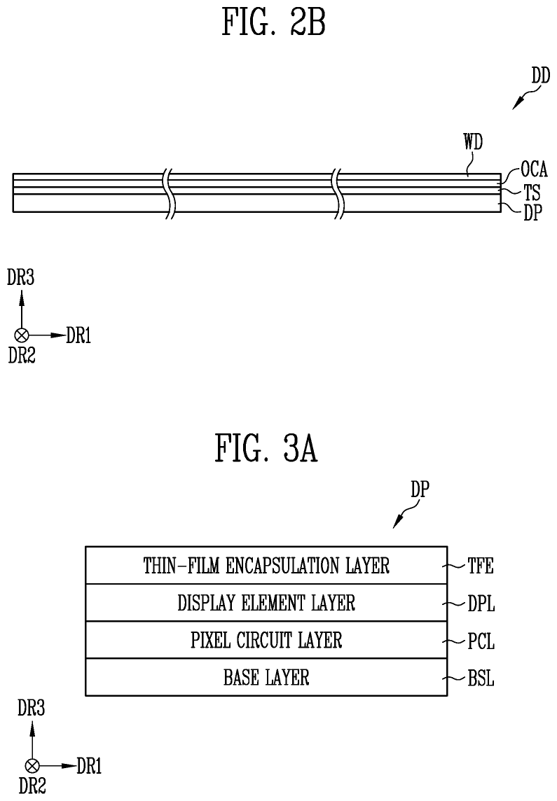

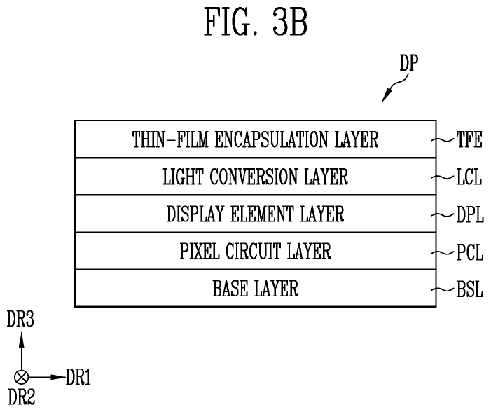

FIG. 1 is a perspective view illustrating a display device DD in accordance with embodiments of the disclosure. FIGS. 2A and 2B are schematic cross-sectional views each illustrating a display device DD in accordance with an embodiment of the disclosure. FIGS. 3A and 3B are schematic cross-sectional views each illustrating a display panel DP in accordance with an embodiment of the disclosure.

Referring to FIG. 1, the display device DD may include a display area DA and a non-display area NA (referred also to as “bezel area”). The display area DA may be an area which includes pixels to display an image. The non-display area NA may be an area other than the display area DA. No image may be displayed in the non-display area NA.

The display area DA may have various shapes, and include pixels arranged in a certain manner. For example, the display area DA may have various shapes including a rectangular shape, a circular shape, an elliptical shape, and the like.

The display area DA may be disposed on at least one surface of the display device DD. For example, the display area DA may be formed on a front surface of the display device DD. However, the disclosure is not limited thereto. The display area DA may be additionally formed on a side surface and/or a rear surface of the display device DD.

The non-display area NA may be disposed adjacent to a perimeter of the display area DA, and may optionally include lines, pads, and/or a driving circuit which are/is connected to the pixels of the display area DA. In the case in which the surface area of the non-display area NA is reduced, the size of the display area DA may be increased without increasing the size (e.g., the surface area) of the display device DD. Therefore, a relatively large screen may be provided. Furthermore, in the case where the non-display area NA is reduced, in case that a multi-screen display device is implemented using multiple display devices DD, boundaries between the display devices DD may be minimized from being visible, so that a smoother screen may be formed.

The display device DD may be provided in various shapes. Although, for example, the display device DD is provided in a rectangular planar shape in FIG. 1, embodiments of the disclosure are not limited thereto. For instance, the display device DD may have a shape such as a circular shape or an elliptical shape. Furthermore, although FIG. 1 illustrates that the display device DD includes an angled corner, embodiments of the disclosure are not limited thereto. For example, the display device DD may include a curved corner.

For the convenience of description, FIG. 1 illustrates that the display device DD includes a rectangular planar shape including a pair of long sides and a pair of short sides. An extension direction of the long sides is indicated as a first direction DR1. An extension direction of the short sides is indicated as a second direction DR2. A direction perpendicular to the extension directions of the long sides and the short sides is indicated as a third direction DR3 (e.g., a thickness-wise or height-wise direction of the display device DD). However, the foregoing may be changed in various ways depending on the shape of the display device DD.

The display device DD may have flexibility to allow at least one area thereof to be changed in shape, or may not have flexibility to prevent the overall area thereof from being substantially changed in shape. In other words, the display device DD may be a flexible display device or a rigid display device. In the case where the display device DD has flexibility on at least a portion thereof, the display device DD may be changed in shape in such a way that the portion that has the flexibility may be bent, curved, or rolled.

Referring to FIG. 2A, the display device DD may include a display panel DP and a window WD disposed on the display panel DP. In an embodiment, the window WD may be manufactured to be integrated with the display panel DP. For example, the window WD may be directly formed on one surface of the display panel DP. In an embodiment, the window WD may be manufactured separately from the display panel DP, and thereafter be coupled to the display panel DP by an optically transparent adhesive (e.g., using an adhesive OCA).

The display panel DP may include pixels for displaying an image, and may be of various kinds and/or structures. For example, the display panel DP may be a self-emissive display panel such as an organic light emitting display (OLED) panel using an organic light emitting diode as a light emitting element, a nano-scale LED display (Nano LED) panel using a nano-scale light emitting diode as a light emitting element, a quantum dot organic light emitting display (QD OLED) panel using an organic light emitting diode and a quantum dot, or a quantum dot nano-scale LED display (QD Nano LED) panel using a nano-scale LED and a quantum dot. In another example, the display panel DP may be a non-emissive display panel such as a liquid crystal display (LCD) panel, an electrophoretic display (EPD) panel, or an electrowetting display (EWD) panel. In case that the non-emissive display panel is used as the display panel DP, the display device DD may further include a separate light source (e.g., a backlight unit) configured to supply light to the display panel DP.

The window WD may be provided on the display panel DP to protect an exposed surface of the display panel DP. The window WD may protect the display panel DP from external impact, and provide an input surface and/or a display surface to the user.

The window WD may be made of various materials including glass and plastic, and may have a single-layer or multi-layer structure. In an embodiment, the window WD may have flexibility in at least one area thereof.

Referring to FIG. 2B, the display device DD may further include a touch sensor TS. The display device DD may further include various kinds and/or types of other sensors (e.g., a fingerprint sensor, a pressure sensor, and a temperature sensor), an input sensing device, and/or the like.

The touch sensor TS may be disposed on at least one surface of the display panel DP, and may detect a touch input from the user. For example, the touch sensor TS may be provided on a front surface of the display panel DP (e.g., an upper surface on which an image may be displayed) such that the touch sensor TS is disposed between the display panel DP and the window WD, but embodiments of the disclosure are not limited thereto.

In an embodiment, the touch sensor TS may be manufactured to be integrated with the display panel DP. For instance, sensor electrodes and/or sensor elements for forming the touch sensor TS may be directly formed on at least one surface of the display panel DP.

In an embodiment, the touch sensor TS may be manufactured separately from the display panel DP, and thereafter be provided on the display panel DP. For example, the touch sensor TS may be disposed and/or attached to at least one surface of the display panel DP.

The touch sensor TS may be of various kinds and/or structures. For example, the touch sensor TS may be a self- or mutual-capacitive touch sensor, a resistive touch sensor, piezoelectric touch sensor, an ultrasonic touch sensor, and/or a hybrid touch sensor formed by combining two types.

In the case where the display device DD includes at least one type of sensor including the touch sensor TS, the display device DD may include a sensing area in which the sensor is provided. In an embodiment, the sensing area may be disposed in the display area DA, but the disclosure is not limited thereto.

Referring to FIG. 3A, the display panel DP may include a base layer BSL, a pixel circuit layer PCL, a display element layer DPL, and a thin-film encapsulation layer TFE which are successively disposed on one surface of the base layer BSL. However, the foregoing is only for illustrative purposes, and the structure of the display panel DP is not limited thereto. For example, in an embodiment, the display element layer DPL may be first disposed on one surface of the base layer BSL, and the pixel circuit layer PCL may be disposed on the display element layer DPL.

Some components of the display panel DP may be omitted or replaced with other components. For example, in the case in which the display panel DP is a display panel of a passive display device, the pixel circuit layer PCL may be omitted. Lines for driving the pixels may be directly or electrically connected to and/or formed on the display element layer DPL. Furthermore, in an embodiment, in lieu of forming the thin-film encapsulation layer TFE, an upper substrate may be disposed on one surface of the base layer BSL. The upper substrate may be coupled to the base layer BSL by a sealant.

The base layer BSL may be a rigid or flexible substrate (or film). In an embodiment, in case that the base layer BSL is a rigid substrate, the base layer BSL may be formed of one of a glass substrate, a quartz substrate, a glass ceramic substrate, and a crystalline glass substrate. In an embodiment, in the case where the base layer BSL is a flexible substrate, the base layer BSL may be one of a film substrate and a plastic substrate each of which includes an organic polymer. The base layer BSL may include fiber glass reinforced plastic (FRP).

The pixel circuit layer PCL may be provided on one surface of the base layer BSL. The pixel circuit layer PCL may include circuit elements for forming a pixel circuit of each pixel, and various lines connected to the circuit elements. For example, the pixel circuit layer PCL may include transistors and a storage capacitor which form the pixel circuit of each pixel, and gate lines, data lines, and power lines which are connected to each pixel circuit(s). In an embodiment, the gate lines may include at least scan lines, and may optionally include other kinds of control lines.

The display element layer DPL may be disposed on the pixel circuit layer PCL. The display element layer DPL may include a light emitting element which forms a light source of each pixel. In an embodiment, the light emitting element may be formed of an organic light emitting diode. In an embodiment, the light emitting element may be formed of an inorganic light emitting diode (e.g., a subminiature inorganic light emitting diode having a nanometer or micrometer scale). However, the kind, structure, shape, and/or size of the light emitting element provided in each pixel in accordance with an embodiment is not limited.

The thin-film encapsulation layer TFE may be disposed on the display element layer DPL. The thin-film encapsulation layer TFE may be an encapsulation substrate or have the form of an encapsulation layer having a multi-layer structure. In the case where the thin-film encapsulation layer TFE has the form of an encapsulation layer, the thin-film encapsulation layer TFE may include an inorganic layer and/or an organic layer. For example, the thin-film encapsulation layer TFE may have a structure formed by successively stacking an inorganic layer, an organic layer, and an inorganic layer. The thin-film encapsulation layer TFE may prevent external air or water from permeating the display element layer DPL and the pixel circuit layer PCL, thus protecting the pixels.

Referring to FIG. 3B, the display panel DP may further include a light conversion layer LCL configured to convert light emitted from the display element layer DPL. For example, in the case where the display panel DP emits light in an upper direction (e.g., the third direction DR3) of the display element layer DPL so that an image is displayed on the front surface of the display panel DP, the light conversion layer LCL may be disposed over the display element layer DPL. For example, the light conversion layer LCL may be provided between the display element layer DPL and the thin-film encapsulation layer TFE.

The light conversion layer LCL may include a color filter including color filter material for a certain color, and/or color conversion particles (e.g., quantum dots) corresponding to the certain color so that light generated from the display element layer DPL can be converted. For example, the light conversion layer LCL may allow light of a specific wavelength band among light rays generated from the display element layer DPL to selectively pass therethrough, and/or convert the wavelength band of light generated from the display element layer DPL.

Although FIGS. 3A and 3B schematically illustrate the display panel DP as an emission display panel, the disclosure is not limited thereto. For example, the configuration of the display panel DP may be changed in various ways depending on the type of display device.

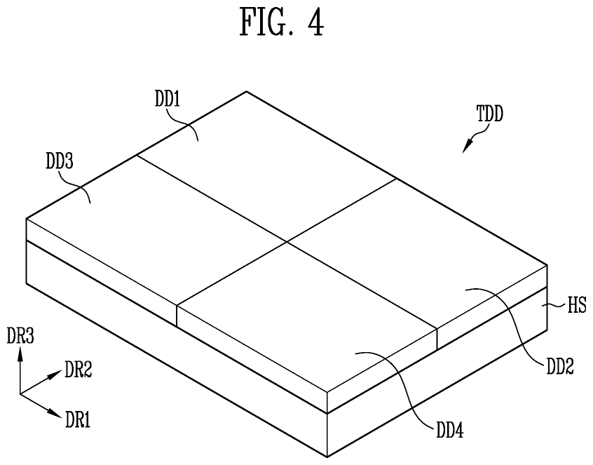

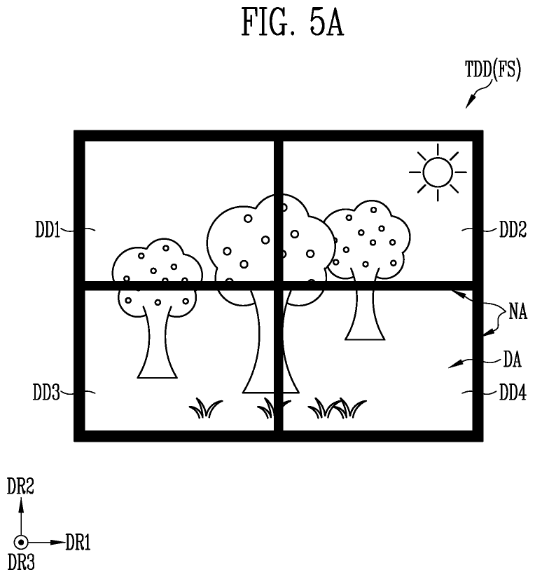

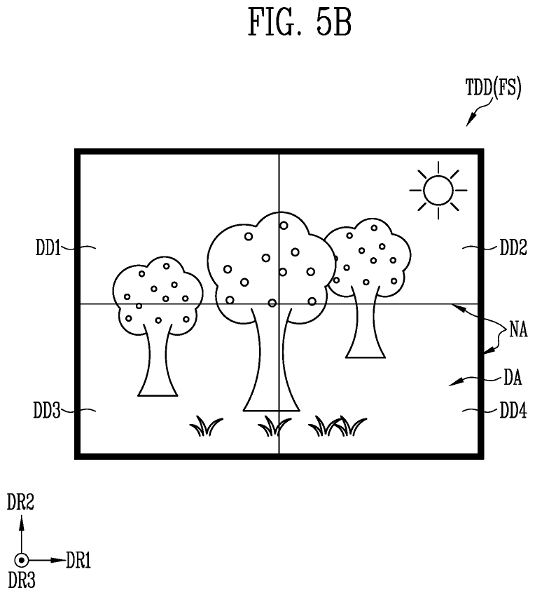

FIG. 4 is a perspective view illustrating a multi-screen display device TDD in accordance with an embodiment of the disclosure. FIGS. 5A and 5B are plan views each illustrating a multi-screen display device TDD in accordance with an embodiment of the disclosure.

Referring to FIG. 4, the multi-screen display device TDD (referred also to as “tiled display”) may include multiple display devices DD1 to DD4 and a housing HS. For example, the multi-screen display device TDD may include the display devices DD1 to DD4 arranged in the form of a matrix in a first and/or second direction DR1 and/or DR2.

The display devices DD1 to DD4 may respectively display individual images or partitively display one image. In an embodiment, the display devices DD1 to DD4 may include display panels that are the same in type, structure, size, and/or scheme, but embodiments of the disclosure are not limited thereto. For example, the display devices DD1 to DD4 may include display panels that are different from each other in type, structure, size, and/or scheme.

The housing HS may physically couple the display devices DD1 to DD4 so that the display devices DD1 to DD4 can form one multi-screen display device TDD. The housing HS may be disposed under the display devices DD1 to DD4 to support the display devices DD1 to DD4 thereon, and may have a coupling member, a groove structure, and/or the like for stably fixing the display devices DD1 to DD4.

Referring to FIGS. 5A and 5B, the display devices DD1 to DD4 may display images in the respective display areas DA. Hence, an image displayed on a screen of the multi-screen display device TDD may be disconnected by a portion (e.g., a seam area) of the non-display area NA that is disposed on a boundary area between the display devices DD1 to DD4.

For example, as illustrated in FIG. 5A, in the case where the width and/or surface area of the non-display area NA of each of the display devices DD1 to DD4 is relatively large, a sense of disconnection in the image may be exacerbated on the boundary area between the display devices DD1 to DD4.

On the other hand, as illustrated in FIG. 5B, in the case where the width and/or surface area of the non-display area NA of each of the display devices DD1 to DD4 is reduced or the non-display area NA is substantially removed, a phenomenon in which the boundary area between the display devices DD1 to DD4 is visible may be prevented or mitigated, and the image displayed on the screen may be more smoothly integrated even on the boundary area. Therefore, a sense of disconnection in the image displayed on the screen of the multi-screen display device TDD may be mitigated, so that the screen can be more smoothly formed.

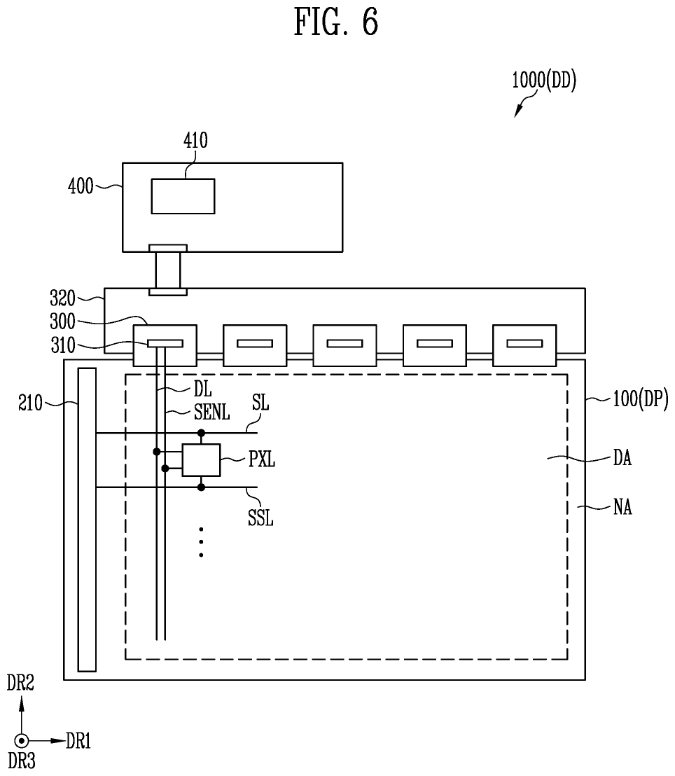

FIG. 6 is a schematic diagram illustrating a display device in accordance with an embodiment of the disclosure.

FIG. 6 illustrates a display device 1000 (DD) including multiple data drivers (or source drive ICs), as an example to which an embodiment of the disclosure can be applied. However, the disclosure is not limited to this. For example, the disclosure may also be applied to a display device including one data driver (or a source drive IC).

Referring to FIG. 6, the display device 1000 (DD) may include a display panel 100 (DP), a scan driver 210 (or a gate driver, or a gate drive IC), a data driver 310 (or a source driver, or a source drive IC), and a timing controller 410. The scan driver 210, the data driver 310, and the timing controller 410 may form a display panel driving device configured to drive the display panel 100.

The display panel 100 may include a display area DA formed to display an image, and a non-display area NA provided adjacent to the periphery of the display area DA. The display panel 100 may include a scan line SL, a sensing control line SSL, a data line DL, a sensing line SENL (or a readout line), and a pixel PXL.

The pixel PXL may be disposed in an area defined by the scan line SL, the sensing control line SSL, the data line DL, and the sensing line SENL. The display panel 100 may include multiple pixels PXL. For example, multiple pixels PXL may be connected to each corresponding data line DL and a corresponding sensing line SENL.

The timing controller 410 may control the scan driver 210 and the data driver 310. The timing controller 410 may receive a control signal (e.g., a control signal including a clock signal) from an external device, and generate a scan control signal (or a gate control signal) and a data control signal based on the control signal. The timing controller 410 may provide the scan control signal to the scan driver 210, and may provide the data control signal to the data driver 310.

Furthermore, the timing controller 410 may realign input data provided from an external device (e.g., a graphic processor) to generate frame data (or image data).

In an embodiment, the timing controller 410 may be mounted on a control board 400.

The scan driver 210 and the data driver 310 may drive the display panel 100.

The scan driver 210 may receive the scan control signal from the timing controller 410 and generate a scan signal and a sensing scan signal based on the scan control signal. The scan driver 210 may provide the scan signal to the scan line SL, and provide the sensing scan signal to the sensing control line SSL.

In an embodiment, the scan driver 210 and the pixels PXL may be formed on the display panel 100.

The disclosure is not limited to this. For example, the scan driver 210 may be mounted on at least one connection film 300 (or a circuit film), and may be connected to the timing controller 410 mounted on the control board 400 via the connection film 300 and a printed circuit board 320.

The data driver 310 may restore frame data in response to the data control signal received from the timing controller 410. Furthermore, during a first period (e.g., a display period during which an image is displayed on the display panel 100), the data driver 310 may generate a data signal corresponding to the frame data and provide the data signal to the data line DL.

During a second period (e.g., a sensing period provided to sense a threshold voltage and/or mobility of a driving transistor included in the pixel PXL as characteristic information of the pixel PXL) different from the first period, the data driver 310 may receive at least one sensing signal (or a sensing value) from at least one pixel among the pixels through the sensing line SENL.

For example, the second period may be a vertical blank period (or a vertical porch period) between the first period and an adjacent first period (e.g., another frame period), and the data driver 310 may receive a sensing signal (e.g., the mobility of the driving transistor, a signal pertaining thereto, or the like) from the pixels PXL. In another example, the second period may be a period immediately before the display device 1000 is powered off, and the data driver 310 may successively receive sensing signals (e.g., threshold voltages of the respective driving transistors of the pixels) from the pixels PXL on a pixel row basis.

The data driver 310 may be mounted on the connection film 300, and may be connected to the timing controller 410 via at least one printed circuit board 320 and/or a cable.

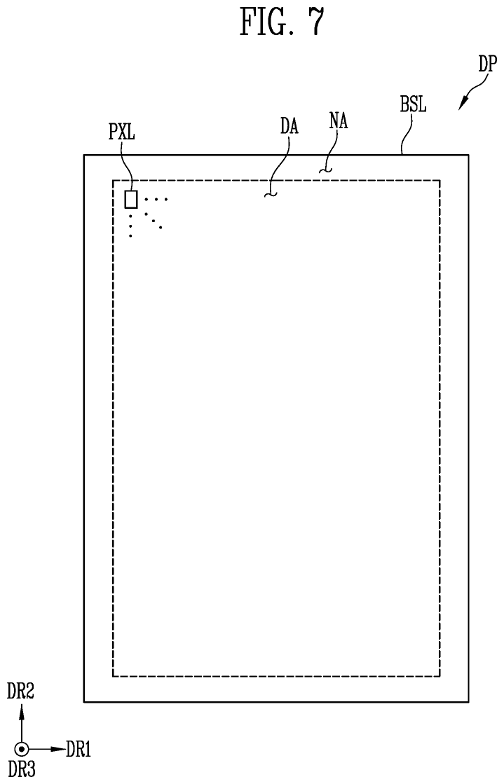

FIG. 7 is a plan view schematically illustrating the display panel DP in accordance with an embodiment of the disclosure.

Referring to FIG. 7, the display panel DP may include a base layer BSL, and pixels PXL disposed on the base layer BSL.

The base layer BSL may be provided as one area having an approximately rectangular shape. However, the disclosure is not limited thereto. The number of areas provided in the base layer BSL may be changed. The shape of the base layer BSL may be changed depending on provided areas.

The base layer BSL may be made of insulating material such as glass or resin. The base layer BSL may be made of material having flexibility so as to be bendable or foldable, and may have a single-layer or multi-layer structure.

The base layer BSL may include a display area DA and a non-display area NA. In other words, the display area DA of the display panel DP may correspond to the display area DA of the display device DD. The non-display area NA of the display panel DP may correspond to the non-display area NA of the display device DD.

The pixels PXL may be provided in the display area DA on the base layer BSL. Each of the pixels PXL may be the smallest unit for displaying an image. The pixels PXL each may include a light emitting element. Each of the pixels PXL may emit any one color of red, green, and blue, but the disclosure is not limited thereto, and the pixel PXL may emit a color such as cyan, magenta, or yellow.

For the sake of explanation, FIG. 7 illustrates only one pixel PXL, but substantially multiple pixels PXL may be dispersedly provided in the display area DA.

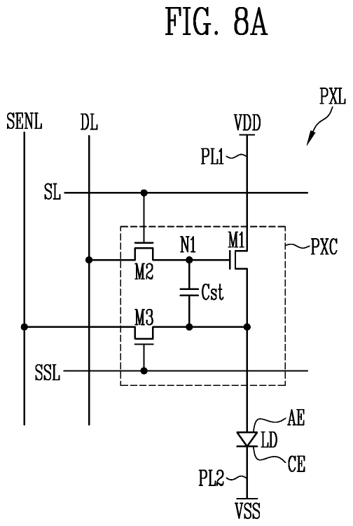

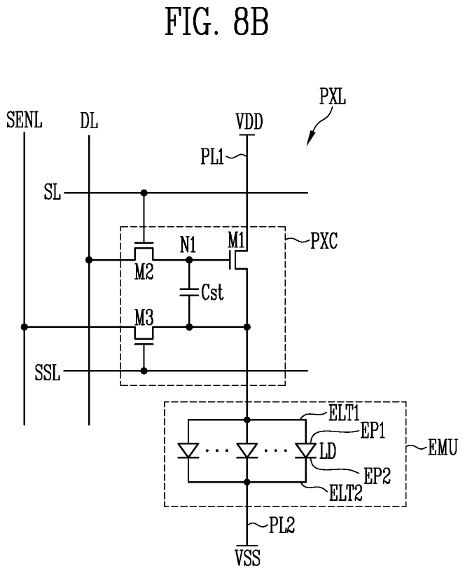

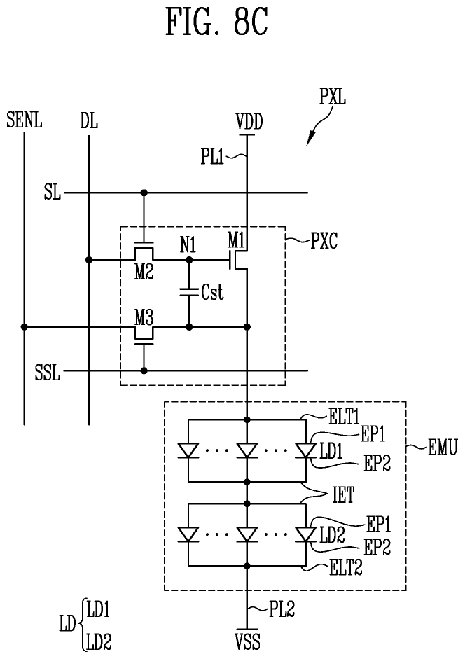

FIGS. 8A to 8C are schematic diagrams of an equivalent circuit of a pixel included in the display panel of FIG. 7.

FIGS. 8A to 8C illustrate different embodiments of the pixel PXL including at least one light emitting element LD. For example, FIG. 8A illustrates an embodiment of the pixel PXL including one light emitting element LD (e.g., an organic light emitting diode). FIGS. 8B and 8C illustrate embodiments of a pixel PXL including multiple light emitting elements LD (e.g., multiple inorganic light emitting diodes).

Referring to FIG. 8A, the pixel PXL may include a light emitting element LD connected between a first power line PL1 to which a voltage of a first power supply VDD is supplied and a second power line PL2 to which a voltage of a second power supply VSS is supplied, and a pixel circuit PXC configured to drive the light emitting element LD.

The pixel circuit PXC may be connected between the first power line PL1 and the light emitting element LD. The pixel circuit PXC may be connected to a scan line SL and a data line DL of the corresponding pixel PXL, and control the operation of the light emitting element LD in response to a scan signal and a data signal supplied from the scan line SL and the data line DL. The pixel circuit PXC may be optionally connected to a sensing control line SSL and a sensing line SENL.

In the description of the embodiments of the disclosure, the term “coupling (or connection)” may collectively refer to physical and/or electrical coupling (or connection). Furthermore, the term “connection (or coupling)” may collectively refer to direct or indirect connection (or coupling) and integral or non-integral connection (or coupling).

The pixel circuit PXC may include at least one transistor and at least one capacitor. For example, the pixel circuit PXC may include a first transistor M1, a second transistor M2, a third transistor M3, and a storage capacitor Cst.

The first transistor M1 may be connected between the first power line PL1 and a first electrode AE (e.g., an anode electrode) of the light emitting element LD. A gate electrode of the first transistor M1 may be connected to the first node N1. The first transistor M1 may control driving current to be supplied to the light emitting element LD in response to a voltage of the first node N1. For example, the first transistor M1 may be a driving transistor configured to control the driving current of the pixel PXL.

In an embodiment, the first transistor M1 may optionally include a back gate electrode. For example, the gate electrode and the back gate electrode of the first transistor M1 may overlap each other with an insulating layer interposed therebetween.

The second transistor M2 may be connected between the data line DL and the first node N1. A gate electrode of the second transistor M2 may be connected to the scan line SL. In case that a scan signal of a gate-on voltage (e.g., a high-level voltage) is supplied from the scan line SL, the second transistor M2 may be turned on to electrically connect the data line DL with the first node N1.

During each frame period, a data signal of the corresponding frame may be supplied to the data line DL, and the data signal may be transmitted to the first node N1 through the second transistor M2 that is turned on during a period which the scan signal having a gate-on voltage is supplied to the scan line SL. In other words, the second transistor M2 may be a switching transistor configured to transmit each data signal to the pixel PXL.

One electrode of the storage capacitor Cst may be connected to the first node N1, and another electrode thereof may be connected to a second electrode of the first transistor M1. The storage capacitor Cst may be charged with a voltage corresponding to a data signal to be supplied to the first node N1 during each frame period.

The third transistor M3 may be connected between the first electrode AE of the light emitting element LD (or the second electrode of the first transistor M1) and the sensing line SENL. A gate electrode of the third transistor M3 may be connected to the sensing control line SSL. The third transistor M3 may transmit a voltage value (e.g., a sensing signal, or a sensing value) applied to the first electrode AE of the light emitting element LD to the sensing line SENL in response to a sensing scan signal supplied to the sensing control line SSL during a certain sensing period (e.g., the sensing period described with reference to FIG. 6). The voltage value transmitted through the sensing line SENL may be provided to an external circuit (e.g., the timing controller 410 of FIG. 6). The external circuit may extract characteristic information of each pixel PXL (e.g., a threshold voltage of the first transistor M1) based on the provided voltage value. The extracted characteristic information may be used to convert image data to compensate for a deviation in characteristics between the pixels PXL.

Although FIG. 8A illustrates that the transistors (e.g., the first to third transistors M1, M2, and M3) included in the pixel circuit PXC are formed of N-type transistors, the disclosure is not limited thereto. For example, at least one of the first to third transistors M1, M2, and M3 may be changed to a P-type transistor. In an embodiment, the pixel circuit PXC may include a combination of P-type and N-type transistors.

The structure and driving scheme of the pixel PXL may be changed in various ways. For instance, the pixel circuit PXC may not only be formed of the pixel circuit of the embodiment illustrated in FIG. 8A but may also be formed of a pixel circuit which has various structures and/or may be operated in various driving schemes.

For example, the pixel circuit PXC may not include the third transistor M3. Furthermore, the pixel circuit PXC may further include other circuit elements such as a compensation transistor configured to compensate the threshold voltage of the first transistor M1, an initialization transistor configured to initialize the first node N1 or the light emitting element LD, an emission control transistor configured to control a period during which driving current is supplied to the light emitting element LD, and/or a boosting capacitor configured to boost the voltage of the first node N1.

The light emitting element LD may include a first electrode AE connected to the first power supply VDD through the pixel circuit PXC and the first power line PL1, and a second electrode CE connected to the second power supply VSS through the second power line PL2. Furthermore, the light emitting element LD may include an emission layer (e.g., an organic emission layer) interposed between the first electrode AE and the second electrode CE.

The first power supply VDD and the second power supply VSS may have different potentials to allow the light emitting element LD to emit light. For example, the first power supply VDD may have a voltage level higher than that of the second power supply VSS. The first electrode AE of the light emitting element LD may be an anode electrode, and the second electrode CE thereof may be a cathode electrode.

In case that driving current is supplied from the pixel circuit PXC, the light emitting element LD may generate light having a luminance corresponding to the driving current. Hence, each pixel PXL may emit light at a luminance corresponding to a data signal supplied to the first node N1 during each frame period. In the case where a data signal corresponding to a black grayscale value is supplied to the first node N1 during the corresponding frame period, the pixel circuit PXC may not supply driving current to the light emitting element LD, so that the pixel PXL may remain in a non-emission state during the corresponding frame period.

Referring to FIG. 8B, the pixel PXL may include an emission component EMU including at least one light emitting element LD connected between the first power line PL1 and the second power line PL2. For example, the emission component EMU may include multiple light emitting elements LD (e.g., inorganic light emitting diodes) connected in parallel to each other between the pixel circuit PXC and the second power line PL2.

For example, the emission component EMU may include a first electrode ELT1 (or a first pixel electrode) connected to the first power supply VDD via the pixel circuit PXC and the first power line PL1, a second electrode ELT2 (or a second pixel electrode) connected to the second power supply VSS through the second power line PL2, and multiple light emitting elements LD which are electrically connected between the first and second electrodes ELT1 and ELT2. In an embodiment, the first electrode ELT1 of the emission component EMU may be an anode electrode, and the second electrode ELT2 thereof may be a cathode electrode, but the disclosure is not limited thereto.

In an embodiment, the emission component EMU may include multiple light emitting elements LD which are connected in parallel to each other and arranged in a direction between the first electrode ELT1 and the second electrode ELT2. For example, each of the light emitting elements LD may include a first end EP1 (e.g., a P-type end) connected to the first power supply VDD through the first electrode ELT1 and/or the pixel circuit PXC, and a second end EP2 (e.g., an N-type end) connected to the second power supply VSS through the second electrode ELT2. In other words, the light emitting elements LD may be connected in parallel in a forward direction between the first and second electrodes ELT1 and ELT2.

Although FIG. 8B illustrates an embodiment in which the pixel PXL includes the emission component EMU having a parallel structure, the disclosure is not limited thereto. For example, the pixel PXL may include an emission component EMU having a series structure or a series/parallel structure. For example, the emission component EMU may include light emitting elements LD connected in series or a portion in series and another portion in parallel between the first electrode ELT1 and the second electrode ELT2. For example, the emission component EMU may include multiple light emitting elements LD divided into two series stages, as illustrated in the embodiment of FIG. 8C.

For example, referring to FIG. 8C, the emission component EMU may include a first electrode ELT1, a second electrode ELT2, and multiple light emitting elements LD which are connected in series/parallel structure between the first and second electrodes ELT1 and ELT2.

For example, the emission component EMU may include the first electrode ELT1, the second electrode ELT2, and at least one intermediate electrode IET connected between the first and second electrodes ELT1 and ELT2. Some of the light emitting elements LD may be connected in the forward direction between the first electrode ELT1 and the intermediate electrode IET. The other light emitting elements LD may be connected in the forward direction between the intermediate electrode IET and the second electrode ELT2. Therefore, the light emitting elements LD may be connected in series/parallel to each other between the first electrode ELT1 and the second electrode ELT2.

For example, at least one first light emitting element LD1 may be connected between the first electrode ELT1 and the intermediate electrode IET. The first light emitting element LD1 may include a P-type first end EP1 connected to the first electrode ELT1, and an N-type second end EP2 connected to the intermediate electrode IET.

At least one second light emitting element LD2 may be connected between the intermediate electrode IET and the second electrode ELT2. The second light emitting element LD2 may include a P-type first end EP1 connected to the intermediate electrode IET, and an N-type second end EP2 connected to the second electrode ELT2. In an embodiment, the number of second light emitting elements LD2 may be identical to or different from the number of first light emitting elements LD1.

Although FIG. 8C illustrates the emission component EMU having a two-stage series/parallel structure, the disclosure is not limited thereto. For example, the emission component EMU may have a three- or more-stage series structure and/or series/parallel combination structure.

On the assumption that the emission component EMU is configured using the light emitting elements LD having the same conditions (e.g., the same size and/or number) as valid light sources, in case that the light emitting elements LD are connected to each other in series or series/parallel combination structure, the power efficiency can be enhanced. For example, in the case of the emission component EMU (e.g., the emission component EMU of FIG. 8C) in which the light emitting elements LD are connected in series or in series/parallel, the luminance that can be expressed may be higher than that of the emission component (e.g., the emission component EMU of FIG. 8B) in which the light emitting elements LD are connected only in parallel, under conditions of the same current. Furthermore, in the emission component EMU in which the light emitting elements LD are connected in series or series/parallel structure, driving current needed to express the same luminance may be reduced, compared to that of the emission component EMU in which the light emitting elements LD are connected in parallel to each other.

Furthermore, in the pixel PXL in which the light emitting elements LD are connected in series or in a series/parallel combination structure, even if a short-circuit defect or the like occurs in some series stages, a certain degree of luminance can be expressed by the light emitting elements LD of the other series stages, so that the probability of occurrence of a black spot defect in the pixel PXL can be mitigated (or removed).

In the embodiments of FIGS. 8B and 8C, each of the light emitting elements LD may include a first end EP1 (e.g., a P-type end) connected to the first power supply VDD via the first pixel electrode (e.g., the first electrode ELT1), the pixel circuit PXC, and/or the first power line PL1, and the like, and a second end EP2 (e.g., an N-type end) connected to the second power supply VSS via the second pixel electrode (e.g., the second electrode ELT2), the second power line PL2, and the like. In other words, the light emitting elements LD may be connected in the forward direction between the first power supply VDD and the second power supply VSS.

Each of the light emitting elements LD connected in the forward direction between the first power supply VDD and the second power supply VSS may form a valid light source. Such valid light sources may form the emission component EMU of the pixel PXL.

The light emitting elements LD may emit, in case that driving current is supplied thereto through the corresponding pixel circuit PXC, light having a luminance corresponding to the driving current. For example, during each frame period, the pixel circuit PXC may supply driving current corresponding to a grayscale value to be represented in the corresponding frame to the emission component EMU. Hence, the light emitting elements LD may emit light having a luminance corresponding to the driving current, so that the emission component EMU may represent the luminance corresponding to the driving current.

In an embodiment, the emission component EMU may include at least one invalid light source, as well as valid light sources. For example, in at least one series stage, at least one invalid light emitting element which is oriented in a reverse direction, or which has at least one end that floats, may be provided. The invalid light emitting element may remain in a disabled state even in case that a certain driving voltage (e.g., a forward driving voltage) is applied between the first and second electrodes ELT1 and ELT2, and thus remain in a substantially non-emission state.

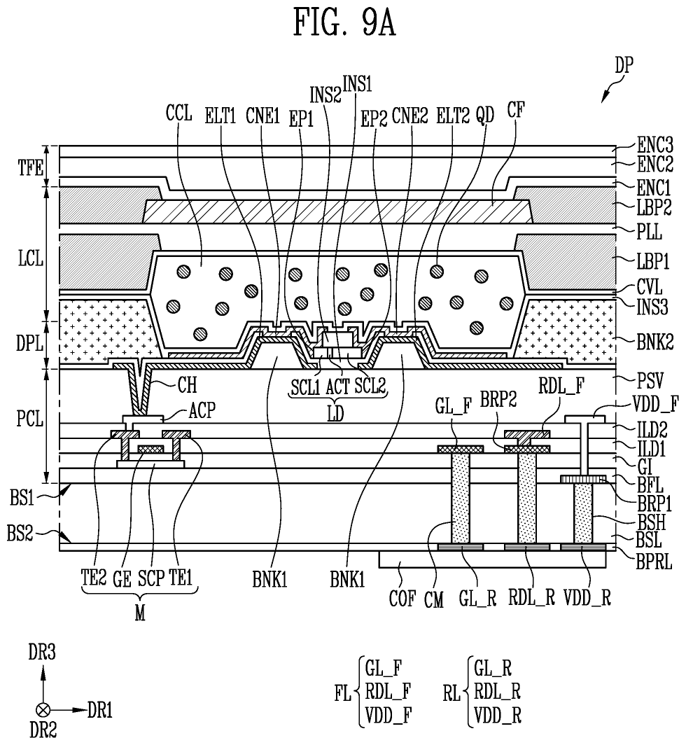

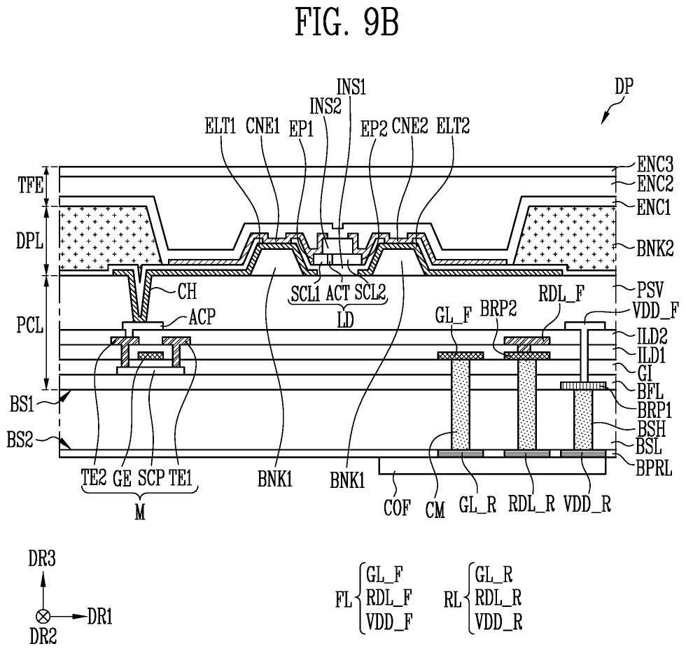

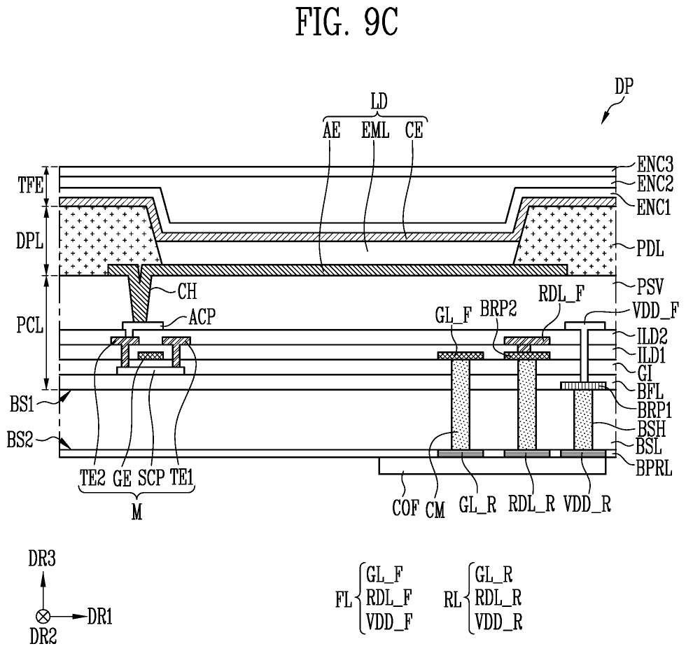

FIGS. 9A to 9C are schematic cross-sectional views each illustrating a display panel DP in accordance with an embodiment of the disclosure.

Referring to FIG. 9A, the display panel DP in accordance with an embodiment may include a pixel circuit layer PCL, a display element layer DPL, and a thin-film encapsulation layer TFE which are successively disposed in the third direction DR3 on a first surface BS1 of a base layer BSL. However, the foregoing is for illustrative purposes, and the arrangement (or the stacking relationship) of the pixel circuit layer PCL, the display element layer DPL, and the thin-film encapsulation layer TFE may be changed depending on embodiments.

The base layer BSL may include a base hole BSH passing through the first surface BS1 and a second surface BS2. The base hole BSH may be charged (or filled) with conductive material CM. The conductive material CM charged into the base hole BSH may directly (or electrically) contact a first line FL and a second line RL, which are respectively disposed on the first surface BS1 and the second surface BS2, so that the first line FL and the second line RL that are respectively disposed on the first surface BS1 and the second surface BS2 can be electrically and physically connected to each other. For example, the base layer BSL may be formed of glass, quartz, glass ceramic, or the like.

The pixel circuit layer PCL may include a circuit element which forms the pixel circuit of each of the pixels (e.g., the pixels PXL of FIG. 8A) and a first line FL connected to the pixel circuit of the pixel (e.g., the pixel PXL of FIG. 7) and the light emitting element LD.

The circuit element may include a transistor M, a capacitor (not illustrated), and the like. The first line FL may include at least one first gate line GL_F (referred also to as “front gate line”), a first data line RDL_F (referring also to as “front data line”), and a first driving voltage line VDD_F (referred also to as “front driving voltage line”) which can be electrically connected to the circuit element. Although not illustrated in FIG. 9A, the first line FL may also include a front sensing line for detecting characteristic information of the pixel PXL. For example, the front sensing line and the first data line RDL_F may be disposed on a same layer.

The first line FL may be lines disposed on the first surface BS1 of the base layer BSL, and may be electrically connected to the second line RL disposed on the second surface BS2 of the base layer BSL. A first bridge pattern BRP1 disposed on the first surface BS1 may electrically connect a second driving voltage line VDD_R (or a rear driving voltage line) to be described below to the first driving voltage line VDD_F.

The second line RL may include at least one second gate line GL_R (referred also to as “rear gate line”), a second data line RDL_R (referred also to as “rear data line”), and a second driving voltage line VDD_R (referred also to as “rear driving voltage line”). Although not illustrate in FIG. 9A, the second line RL may also include rear sensing lines for detecting the characteristic information of the pixel PXL. For example, the rear sensing line and the second data line RDL_R may be disposed on a same layer.

The second line RL may be formed to overlap the first line FL at a position corresponding to the first line FL in the third direction DR3 so that the second line RL may be connected to the first line FL. The second gate line GL_R may be electrically and/or physically connected to the first gate line GL_F through the base hole BSH. The second data line RDL_R may be electrically and/or physically connected to the first data line RDL_F through the base hole BSH and a second bridge pattern BRP2. The second driving voltage line VDD_R may be electrically and/or physically connected to the first driving voltage line VDD_F through the base hole BSH and the first bridge pattern BRP1. As described above, in the case where the first line FL and the second line RL respectively further include the front sensing line and the rear sensing line, the rear sensing line may be electrically and/or physically connected to the front sensing line through the base hole. In an embodiment, the second line RL and the conductive material CM of the base hole BSH may be integral with each other.

A first protective layer BPRL (or a first lower protective layer) may be disposed on the second surface BS2 of the base layer BSL to cover the second line RL. The first protective layer BPRL may be an organic insulating layer including organic material, however, the disclosure is not limited thereto. In an embodiment, the first protective layer BPRL may be an inorganic insulating layer including inorganic material. The first protective layer BPRL may be disposed on an overall surface of the second surface BS2 of the base layer BSL including the second line RL, and expose at least a portion of the second line RL in a certain area. At least the exposed portion of the second line RL may contact a connection film COF which will be described below.

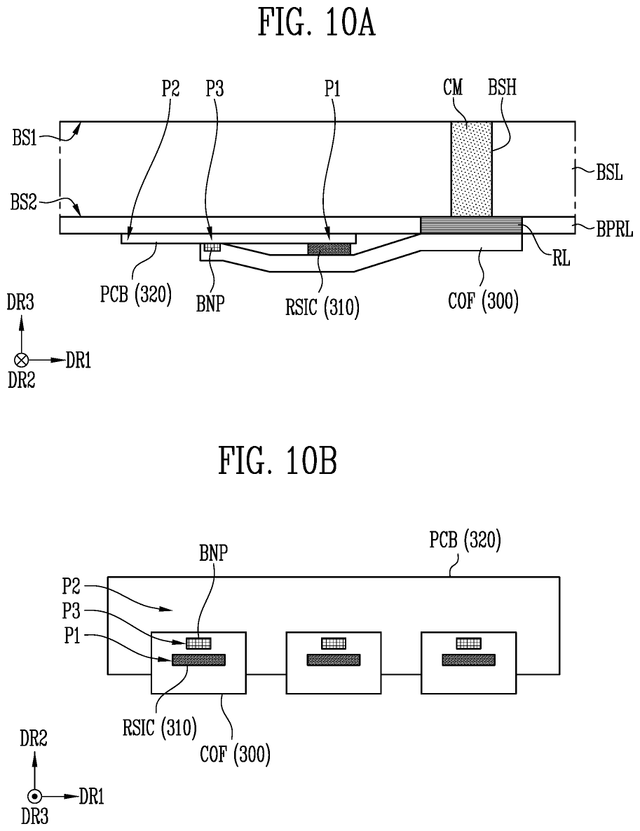

The second line RL may be electrically connected to a driving circuit (e.g., a driving circuit RSIC of FIG. 10A) through the connection film COF. For example, the driving circuit (e.g., the driving circuit RSIC of FIG. 10A) may be mounted on the connection film COF disposed on the rear surface of the second line RL. In an embodiment, the driving circuit (e.g., the driving circuit RSIC of FIG. 10A) may be a data driver (e.g., the data driver 310 described with reference to FIG. 6), a gate driver (e.g., the scan driver 210), and/or a power driver.

In an embodiment, the connection film COF may be provided in the form of a chip-on-film, however, the disclosure is not limited thereto.

The second gate line GL_R may be electrically connected to the gate driver through the connection film COF. The second data line RDL_R may be electrically connected to the data driver through the connection film COF. The second driving voltage line VDD_R may be electrically connected to the power driver through the connection film COF.

Although the foregoing description has been made based on the structure in which the gate driver (e.g., the scan driver 210 of FIG. 6), the data driver (e.g., the data driver 310 of FIG. 6) (or the driving circuit), and the power driver are mounted on one (or the same) connection film COF (i.e., the second line RL is electrically connected to the gate driver, the data driver, and the power driver through one (or the same) connection film COF), the disclosure is not limited thereto. In an embodiment, the gate driver, the data driver, and the like may be respectively mounted on separate connection films COF separated from each other. The rear gate line GL_R and the rear data line RDL_R may be respectively connected to the gate driver and the data driver by separate connection films COF.

The pixel circuit layer PCL may include different kinds of signal lines or the like which are connected to the pixels PXL.

The pixel circuit layer PCL may include multiple insulating layers. For example, the pixel circuit layer PCL may include a buffer layer BFL, a gate insulating layer GI, a first interlayer insulating layer ILD1, a second interlayer insulating layer ILD2, and a passivation layer PSV, which are successively disposed on the first surface BS1 of the base layer BSL in the third direction DR3.

The first bridge pattern BRP1 may be disposed between the base layer BSL and the buffer layer BFL. The first bridge pattern BRP1 may physically and/or electrically connect the first driving voltage line VDD_F and the second driving voltage line VDD_R to each other.

A semiconductor layer may be disposed on the buffer layer BFL. The semiconductor layer may include a first semiconductor pattern SCP, and may include a semiconductor pattern of each transistor among multiple transistors. The first semiconductor pattern SCP may include a channel area which overlaps the first gate electrode GE, and a first source area and a first drain area which are disposed on opposite sides of the channel area. Furthermore, the first bridge pattern BRP1 may be disposed on the buffer layer BFL.

The gate insulating layer GI may be disposed on the semiconductor layer. The gate insulating layer GI may include inorganic material such as silicon oxide (SiOₓ), silicon nitride (SiNₓ), silicon oxynitride (SiOₓN_{y}), and the like.

A gate conductor may be disposed on the gate insulating layer GI. The gate conductor may include the first gate electrode GE. The first gate electrode GE may be disposed to overlap the channel area of the first semiconductor pattern SCP. The gate conductor may include the gate electrode of each transistor among multiple transistors, one electrode of the storage capacitor, a first gate line GL_F, a second bridge pattern BRP2, and the like.

The first interlayer insulating layer ILD1 may be disposed on the gate conductor.

A first data conductor may be disposed on the first interlayer insulating layer ILD1. The first data conductor may include the first electrode TE1 and the second electrode TE2 of the transistor M. The first electrode TE1 may be a source electrode connected to the first source area of the first semiconductor pattern SCP. The second electrode TE2 may be a drain electrode connected to the first drain area of the first semiconductor pattern SCP. However, the disclosure is not limited thereto. The first electrode TE1 may be a drain electrode of the transistor M, and the second electrode TE2 may be a source electrode. The first data conductor may include the first electrode TE1 and the second electrode TE2 of each transistor M among multiple transistors, and may include another electrode of the storage capacitor, the first data line RDL_F, and the like.

The second interlayer insulating layer ILD2 may be disposed on the first data conductor.

A second data conductor may be disposed on the second interlayer insulating layer ILD2. The second data conductor may include an anode connection pattern ACP which connects the pixel circuit layer PCL with the display element layer DPL. The second data conductor may also include a first driving voltage line VDD_F, a driving low-voltage line (not illustrated), and the like. The anode connection pattern ACP may be connected to the first electrode ELT1 of the light emitting element LD of each pixel PXL through a contact hole CH. For example, the light emitting element LD may be an organic light emitting diode or at least one subminiature inorganic light emitting diode.

The passivation layer PSV may be disposed on the second data conductor. The display element layer DPL may be disposed on the passivation layer PSV of the pixel circuit layer PCL. The anode connection pattern ACP of the pixel circuit layer PCL and the first electrode ELT1 of the display element layer DPL may be connected to each other through a contact hole CH of the passivation layer PSV.

The display element layer DPL may include light emitting elements LD of the pixels PXL, and electrodes connected to the light emitting elements LD. Each light emitting element LD may be a subminiature inorganic light emitting diode which ranges from the nanometer scale to the micrometer scale and has a structure formed by growing a nitride-based semiconductor. In an embodiment, each light emitting element LD may be a pillar-shaped subminiature inorganic light emitting diode having an aspect ratio greater than 1, but the disclosure is not limited thereto.

The display element layer DPL may include a first bank BNK1, a second bank BNK2, a first electrode ETL1, a second electrode ETL2, a first insulating layer INS1, a second insulating layer INS2, a first contact electrode CNE1, and a second contact electrode CNE2.

The first bank BNK1 may be disposed on the passivation layer PSV. In each pixel PXL, the first bank BNK1 may be disposed in an emission area from which light may be emitted. The first bank BNK1 may be disposed under portions of the first electrode ELT1 and the second electrode ELT2 to protrude the portions of the first electrode ELT1 and the second electrode ELT2 upward (e.g., in the third direction DR3) so that light emitted from the light emitting element LD may be guided in an image display direction of the display device (e.g., in an upper direction of each pixel PXL). The first bank BNK1 may be formed of an inorganic insulating layer including inorganic material, or an organic insulating layer including organic material. In an embodiment, the first bank BNK1 may include an organic insulating layer having a single layer structure or an inorganic insulating layer having a single layer structure, but the disclosure is not limited thereto.

The second bank BNK2 may be disposed on the passivation layer PSV. The second bank BNK2 may be a structure for defining an emission area of each of the pixels PXL, and may be disposed in a non-emission area of each pixel PXL and a non-emission area between the pixels PXL so that the emission area of each pixel PXL can be enclosed by the second bank BNK2. For example, the second bank BNK2 may be a pixel defining layer or may have a dam structure. The second bank BNK2 may include at least one light blocking material and/or reflective material.

The first electrode ELT1 and the second electrode ELT2 each may be disposed on the first bank BNK1 and have a surface corresponding to the shape of the first bank BNK1. The first electrode ELT1 and the second electrode ELT2 may be made of material having a uniform reflectivity. Therefore, light emitted from the light emitting element LD may travel in the image display direction of the display device by the first electrode ELT1 and the second electrode ELT2.

The first electrode ELT1 may be electrically connected to the first electrode ELT1 of the transistor M through a contact hole CH passing through the passivation layer PSV. The second electrode ELT2 may be connected to a driving power supply (not illustrated) through at least one contact hole (not illustrated) passing through the passivation layer PSV in an area that is not illustrated. In an embodiment, the first electrode ELT1 may be an anode, and the second electrode ELT2 may be a cathode. The first electrode ELT1 and the second electrode ELT2 each may be an ohmic contact electrode or a Schottky contact electrode, but the disclosure is not limited thereto.

The first insulating layer INS1 may be disposed between the passivation layer PSV and each of the first electrode ELT1 and the second electrode ELT2. The first insulating layer INS1 may be charged into space between the light emitting element LD and the passivation layer PSV, thus reliably supporting the light emitting element LD. The first insulating layer INS1 may be at least one of an inorganic insulating layer and an organic insulating layer, and may have a single-layer structure or a multi-layer structure.

The light emitting elements LD may be disposed on the first insulating layer INS1. At least one light emitting element LD may be disposed between the first electrode ELT1 and the second electrode ELT2. Multiple light emitting elements LD may be disposed between the first electrode ELT1 and the second electrode ELT2. The light emitting elements LD may be connected in parallel to each other.

Each of the light emitting elements LD may emit any one light of certain-color light and white light. In an embodiment, the light emitting elements LD may be provided in a solution in the form which can be sprayed, and may be inputted to each pixel PXL.

The light emitting element LD may include a first semiconductor layer SCL1, an active layer ACT, and a second semiconductor layer SCL2 which are successively disposed in one direction. The light emitting element LD may further include an insulating layer (not illustrated) which encloses outer circumferential surfaces of the first semiconductor layer SCL1, the active layer ACT, and the second semiconductor layer SCL2.

The first semiconductor layer SCL1 may be a first conductive semiconductor. For example, the first semiconductor layer SCL1 may include at least one p-type semiconductor layer. For instance, the first semiconductor layer SCL1 may include a p-type semiconductor layer which includes at least one semiconductor material of InAlGaN, GaN, AlGaN, InGaN, AlN, and InN, and may be doped with a first conductive dopant (or a p-type dopant) such as Mg.

The active layer ACT may have a single-quantum well structure or a multi-quantum well structure. In an embodiment, a material such as AlGaN or AlInGaN may be used to form the active layer ACT, and various other materials may be used to form the active layer ACT. The location of the active layer ACT may be changed in various ways depending on the type of the light emitting element LD. The active layer ACT may emit light having a wavelength ranging from about 400 nm to about 900 nm, and use a double hetero structure.

The second semiconductor layer SCL2 may include a semiconductor layer of a type different from that of the first semiconductor layer SCL1. For example, the second semiconductor layer SCL2 may include at least one n-type semiconductor layer. For instance, the second semiconductor layer SCL2 may include an n-type semiconductor layer which includes any one semiconductor material of InAlGaN, GaN, AlGaN, InGaN, AlN, and InN and may be doped with a second conductive dopant (or an n-type dopant) such as Si, Ge, or Sn.

An end of the light emitting element LD that is toward the first semiconductor layer SCL1 may be the first end EP1 of the light emitting element LD, and another end thereof that is toward the second semiconductor layer SCL2 may be the second end EP2 of the light emitting element LD.

The second insulating layer INS2 may be disposed on portions of the light emitting elements LD. The second insulating layer INS2 may cover a portion of an upper surface of each of the light emitting elements LD such that the first end EP1 and the second end EP2 of each of the light emitting elements LD may be exposed. The second insulating layer INS2 may reliably fix the light emitting elements LD. In the case where space is present between the first insulating layer INS1 and the light emitting elements LD before the second insulating layer INS2 is formed, the space may be at least partially charged with the second insulating layer INS2.

The first contact electrode CNE1 may be provided on the first electrode ELT1 to electrically and/or physically connect the first electrode ELT1 with one end (e.g., the first end EP1) of each of the light emitting elements LD. The first contact electrode CNE1 may be disposed to overlap the first insulating layer INS1, the second insulating layer INS2, and a portion of the light emitting element LD. The first insulating layer INS1 may be removed from a portion on which the first electrode ELT1 is connected to the first contact electrode CNE1, i.e., on a portion on which the first electrode ELT1 directly contacts the first contact electrode CNE1.

The second contact electrode CNE2 may be provided on the second electrode ELT2 to electrically and/or physically connect the second electrode ELT2 with another end (e.g., the second end EP2) of the light emitting elements LD. The second contact electrode CNE2 may be disposed to overlap the first insulating layer INS1, the second insulating layer INS2, and a portion of the light emitting element LD. The first insulating layer INS1 may be removed from a portion on which the second electrode ELT2 is connected to the second contact electrode CNE2, i.e., on a portion on which the second electrode ELT2 directly contacts the second contact electrode CNE2.

The first contact electrode CNE1 and the second contact electrode CNE2 may be formed of transparent conductive materials. Therefore, light that is emitted from each of the light emitting elements LD and reflected by the first electrode ELT1 and the second electrode ELT2 may travel in the image display direction of the display device.

The light conversion layer LCL may be disposed on the display element layer DPL.

The light conversion layer LCL may include at least one of a color conversion layer CCL including a quantum dot QD, and a color filter CF which is disposed on the display element layer DPL or the color conversion layer CCL. The light conversion layer LCL may further include a cover layer CVL, a first light blocking pattern LBP1, a planarization layer PLL, and a second light blocking pattern LBP2.

In an embodiment, in the case in which the light conversion layer LCL is directly formed on the display element layer DPL, the display element layer DPL may further include a third insulating layer INS3. The third insulating layer INS3 may include at least one organic layer or inorganic layer, and may be disposed on the entirety of a surface of the display element layer DPL.

The color conversion layer CCL may be disposed over the light emitting element LD, and may include color conversion particles (e.g., quantum dots QD converting to a certain color) for converting a first color of light emitted from the light emitting element LD to a second color of light.

For example, in the case where at least one pixel PXL is set to a red (or green) pixel PXL and a blue light emitting element LD is disposed as a light source of the pixel PXL, the color conversion layer CCL including red (or green) quantum dots QD for converting blue light to red (or green) light may be disposed over the light emitting element LD. A red (or green) color filter CF may be disposed over the color conversion layer CCL.

A cover layer CVL for protecting the color conversion layer CCL may be disposed on the color conversion layer CCL. A first light blocking pattern LBP1 may be disposed on an area corresponding to the periphery of the color conversion layer CCL. Although FIG. 9A illustrates an embodiment in which the first light blocking pattern LBP1 is formed after the color conversion layer CCL is first formed, the disclosure is not limited thereto. For example, depending on a processing method used to form the color conversion layer CCL and the performance of equipment, a sequence of forming the color conversion layer CCL and the first light blocking pattern LBP1 may be changed.

The planarization layer PLL may be disposed on the cover layer CVL and the first light blocking pattern LBP1. The planarization layer PLL may planarize upper surfaces of the color conversion layer CCL and the first light blocking pattern LBP1, and may include organic material or inorganic material.

In each pixel PXL, the color filter CF may be disposed in an emission area from which light may be emitted. The color filter CF may include color filter material allowing light of a color corresponding to the color of each pixel PXL to selectively pass therethrough. The second light blocking pattern LBP2 may be disposed on the periphery of the color filter CF.

The thin-film encapsulation layer TFE may be disposed on the light conversion layer LCL.

The thin-film encapsulation layer TFE may have a single- or multi-layer structure. In an embodiment, the thin-film encapsulation layer TFE may include multiple insulating layers which cover the display element layer DPL. For example, the thin-film encapsulation layer TFE may include at least one inorganic layer and at least one organic layer.

For example, the thin-film encapsulation layer TFE may have a structure formed by alternately stacking inorganic layers and organic layers each other. In an embodiment, the thin-film encapsulation layer TFE may include a first encapsulation layer ENC1, a second encapsulation layer ENC2, and a third encapsulation layer ENC3. The first encapsulation layer ENC1 may be disposed on the display element layer DPL and located over the display area (DA of FIG. 1) and at least a portion of the non-display area (NA of FIG. 1). The second encapsulation layer ENC2 may be disposed on the first encapsulation layer ENC1, and located over the display area DA and at least a portion of the non-display area NA. The third encapsulation layer ENC3 may be disposed on the second encapsulation layer ENC2, and located over the display area DA and at least a portion of the non-display area NA. In an embodiment, the first encapsulation layer ENC1, the second encapsulation layer ENC2, and the third encapsulation layer ENC3 each may be formed of an inorganic layer including inorganic material. In another embodiment, the second encapsulation layer ENC2 may be formed of an organic layer including organic material.

Referring to FIG. 9B, the thin-film encapsulation layer TFE may be directly disposed on the display element layer DPL of the display panel DP in accordance with an embodiment. For example, the display panel DP of FIG. 9B may not include the light conversion layer LCL described with reference to FIG. 9A, so that the thickness of the display panel DP can be reduced.

Referring to FIG. 9C, the display panel DP in accordance with an embodiment may include an organic light emitting diode as the light emitting element LD. The base layer BSL, the pixel circuit layer PCL, and the thin-film encapsulation layer TFE are the same as those described with reference to FIG. 9A; therefore, the following description will be made based on the display element layer DPL.

In the embodiment of FIG. 9C, the display element layer DPL may include, as the light emitting element LD, an organic light emitting diode including a first electrode AE, an emission layer EML, and a second electrode CE.

One of the first electrode AE and the second electrode CE may be an anode, and another electrode may be a cathode. In the case where the light emitting element LD is a top-emission type organic light emitting diode, the first electrode AE may be a reflective electrode, and the second electrode CE may be a transmissive electrode. In an embodiment of the disclosure, an embodiment will be described in which the light emitting element LD is a top-emission type organic light-emitting diode and the first electrode AE is an anode.

The first electrode AE may be connected to the second electrode TE2 of the transistor M of the pixel circuit layer PCL through the anode connection pattern ACP and a contact hole CH passing through the passivation layer PSV. The first electrode AE may include a reflective layer (not illustrated) which may reflect light, and a transparent conductive layer (not illustrated) which is disposed over or under the reflective layer. For example, the first electrode AE may be formed of multiple conductive layers including a lower transparent conductive layer and an upper transparent conductive layer each of which is made of indium tin oxide (ITO), and a reflective layer which is provided between the lower transparent conductive layer and the upper transparent conductive layer and is made of silver (Ag).

The display element layer DPL may further include a pixel defining layer PDL having an opening through which a portion of the first electrode AE, e.g., an upper surface of the first electrode AE, is exposed. The pixel defining layer PDL may have a configuration corresponding to the second bank BNK2 of the display panel DP described with reference to FIG. 9A. The pixel defining layer PDL and the second bank BNK2 may have a substantially similar or identical configuration. The pixel defining layer PDL may be an organic insulating layer including organic material. For example, the pixel defining layer PDL may be formed of an organic insulating layer made of material such as an acryl resin, an epoxy resin, a phenolic resin, a polyamide resin, or a polyimide resin.

The emission layer EML may be disposed in an area corresponding to the opening. In other words, the emission layer EML may be disposed on one surface of the exposed first electrode AE. The emission layer EML may have a multilayer thin-film structure including a light generation layer. The emission layer EML may include: a hole injection layer into which holes are injected; a hole transport layer which has excellent hole transportation performance and restrains movement of electrons that have not been coupled with holes in the light generation layer and thus increases chances of recombination between holes and electrons; the light generation layer which emits light by recombination between injected electrons and holes; a hole blocking layer which restrains movement of holes that have not been coupled with electrons in the light generation layer; an electron transport layer which is provided to smoothly transport electrons to the light generation layer; and an electron injection layer into which electrons are injected.

The light generation layer may be individually formed in the emission area of each pixel PXL. The hole injection layer, the hole transport layer, the hole blocking layer, the electron transport layer, and the electron injection layer may be a common layer which integrally extends between adjacent emission areas. FIG. 9C illustrates the emission layer EML that includes the light generation layer.

The second electrode CE may be disposed on the emission layer EML. The second electrode CE may be a common layer provided in common in the pixels PXL, but the disclosure is not limited thereto. The second electrode CE may be provided as a transparent electrode, and include transparent conductive material (or substance). The transparent conductive material (or substance) may include at least one of transparent conductive oxides such as indium tin oxide (ITO), indium zinc oxide (IZO), zinc oxide (ZnO), and indium tin zinc oxide (ITZO), and a conductive polymer such as PEDOT, but the disclosure is not limited thereto.

FIG. 10A is a schematic partial cross-sectional view of the display device in accordance with an embodiment of the disclosure. FIG. 10B is a plan view for describing an arrangement of a connection film, a driving circuit, and a printed circuit board that are included in the display device of FIG. 10A in accordance with an embodiment of the disclosure.

A base layer BSL, a base hole BSH, a conductive material CM, a first protective layer BPRL, a second line RL, and a connection film COF (300) that are illustrated in FIG. 10A are respectively substantially identical or similar to the base layer BSL, the base hole BSH included in the base layer BSL, the conductive material CM disposed inside the base hole BSH, the first protective layer BPRL disposed on the second surface BS2 of the base layer BSL, the second line RL, and the connection film COF that contacts the second line RL described with reference to FIG. 9A, therefore, repetitive explanation thereof will be omitted.

The connection film COF, a driving circuit RSIC, and a printed circuit board PCB of FIG. 10A may respectively correspond to the connection film 300, the data driver 310, and the printed circuit board 320, which are described with reference to FIG. 6.

Referring to FIGS. 9A and 10A, the display device (e.g., the display device DD of FIG. 1) in accordance with embodiments of the disclosure may include the connection film COF, the driving circuit RSIC, and the printed circuit board PCB which are located under the display panel DP (e.g., the second surface BS2 of the base layer BSL).

The driving circuit RSIC may be mounted on the connection film COF. In an embodiment, the driving circuit RSIC may be disposed on the connection film COF. For example, the driving circuit RSIC may be disposed between the second surface BS2 of the base layer BSL and the connection film COF, and may be mounted on the connection film COF.

As described with reference to FIG. 9A, at least the exposed portion of the second line RL may contact the connection film COF. For example, a first end of the connection film COF may contact at least the exposed portion of the second line RL. Therefore, the second line RL may be electrically connected to the driving circuit RSIC through the connection film COF, and may receive signals provided from the driving circuit RSIC, and provide a signal to the driving circuit RSIC. For example, the second line RL may be supplied with a data signal, a gate signal (e.g., a scan signal, and a sensing scan signal), and the like from the driving circuit RSIC through the connection film COF, and provide a sensing signal (e.g., the mobility of the driving transistor, a signal pertaining thereto, or the like) to the driving circuit RSIC through the connection film COF.

A second end of the connection film COF may contact the printed circuit board PCB. For example, the second end of the connection film COF may contact the printed circuit board PCB by a bonding pad BNP. The bonding pad BNP may include a pad electrode provided to electrically connect the connection film COF to the printed circuit board PCB. For example, the pad electrode may include at least one metal material such as Mo, Al, Cu, and Ti, but embodiments of the disclosure are not limited thereto.

The printed circuit board PCB may include a connector (not illustrated) provided to receive an external signal, and metal lines provided to process signals. For example, the printed circuit board PCB may receive, through a connector, control signals (e.g., a data control signal, or a gate control signal) from the timing controller 410 mounted on the control board 400 described with reference to FIG. 6. The printed circuit board PCB may provide, to the connection film COF, control signals (e.g., the data control signal, or the gate control signal) received through the connector.

A signal transmitting or receiving operation of the driving circuit RSIC may increase a temperature of the driving circuit RSIC. Because of heat generated from the driving circuit RSIC, characteristics of the light emitting elements LD included in the display panel DP may be changed. For example, in the case where the driving circuit RSIC directly contacts the display panel DP (e.g., the base layer BSL and the first protective layer BPRL which are included in the display panel DP), heat generated from the driving circuit RSIC may be directly applied to the display panel DP, so that the characteristics of the light emitting element LD included in the display panel DP may be changed. Consequently, the reliability of the light emitting element LD may deteriorate.

Therefore, the driving circuit RSIC included in the display device in accordance with an embodiment of the disclosure may be disposed between the printed circuit board PCB and the connection film COF.

For example, the driving circuit RSIC may be disposed on a lower surface (for example, a rear surface) of the printed circuit board PCB. For instance, the driving circuit RSIC may be disposed between the printed circuit board PCB and the connection film COF at a first point P1 corresponding to a first end of the printed circuit board PCB.

As the driving circuit RSIC is disposed between the printed circuit board PCB and the connection film COF, the connection film COF may be electrically connected (or brought into contact) with the printed circuit board PCB in an area between the first end and the second end of the printed circuit board PCB. For example, the connection film COF may contact the printed circuit board PCB through the bonding pad BNP at a third point P3 between a first point P1 corresponding to the first end of the printed circuit board PCB and a second point P2 corresponding to the second end of the printed circuit board PCB. However, this is only for illustrative purposes. Embodiments of the disclosure are not limited thereto. For example, the connection film COF may contact the printed circuit substrate PCB through the bonding pad BNP at the second point P2 corresponding to the second end of the printed circuit board PCB.

In an embodiment, because the driving circuit RSIC is disposed between the printed circuit board PCB and the connection film COF, the driving circuit RSIC may at least partially overlap the printed circuit board PCB, in a plan view (e.g., based on a surface parallel to the second surface BS2).

For example, referring to FIG. 10B, the driving circuit RSIC may at least partially overlap the printed circuit board PCB in a plan view (e.g., based on a surface that is parallel to the second surface BS2 and is defined by the first direction DR1 and the second direction DR2). For example, the driving circuit RSIC may at least partially overlap the printed circuit board PCB at the first point P1.

As described with reference to FIGS. 10A and 10B, the driving circuit RSIC included in the display device in accordance with an embodiment of the disclosure may be disposed between the printed circuit board PCB and the connection film COF rather than directly contacting the display panel DP. Therefore, influence of heat generated from the driving circuit RSIC on the light emitting element LD included in the display panel DP may be minimized (e.g., removed), so that the reliability of the light emitting element LD can be enhanced.

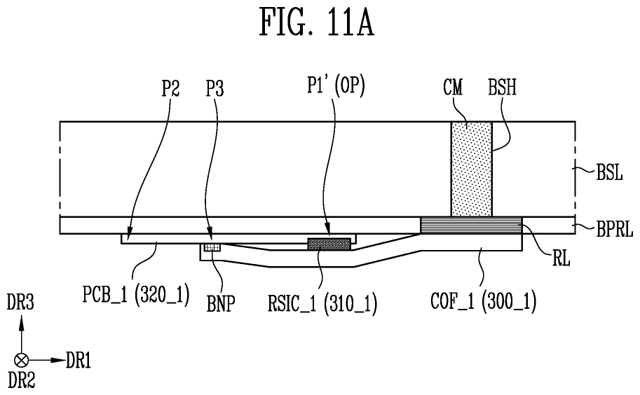

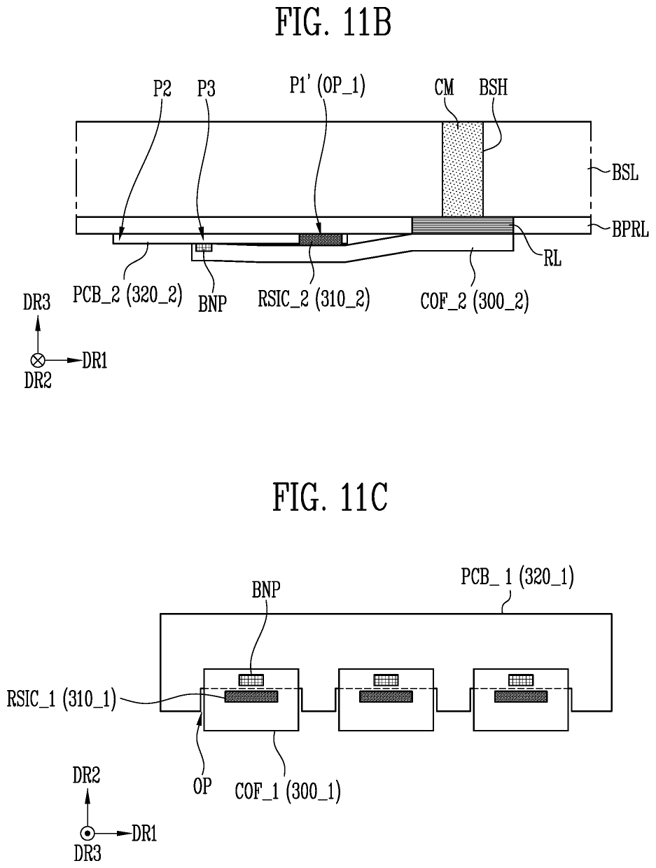

FIG. 11A is a schematic partial cross-sectional view of the display device in accordance with an embodiment of the disclosure. FIG. 11B is a schematic partial cross-sectional view of the display device in accordance with an embodiment of the disclosure. FIG. 11C is a plan view for describing an arrangement of a connection film, a driving circuit, and a printed circuit substrate that are included in the display device of FIG. 11A in accordance with an embodiment of the disclosure.

To avoid redundant explanation, the following description with reference to FIGS. 11A to 11C will be made, based on difference from the foregoing embodiments. Components which are not separately explained in the following description may comply with that of the foregoing embodiments. The same reference numeral will be used to designate the same component, and a similar reference numeral will be used to designate a similar component.

FIGS. 11A and 11B each illustrate a modification of the embodiment of FIG. 10A with regard to the arrangement of the printed circuit board PCB_1 (320_1) and the driving circuit RSIC_1 (310_1). FIG. 11C illustrates a modification of the embodiment of FIG. 10B with regard to the arrangement of the printed circuit board PCB_1 (320_1) and the driving circuit RSIC_1 (310_1).

Referring to FIGS. 9A and 11A, the display device (e.g., the display device DD of FIG. 1) in accordance with embodiments of the disclosure may include a connection film COF_1 (300_1), a driving circuit RSIC_1 (310_1), and a printed circuit board PCB_1 (320_1) which are located under the display panel DP (e.g., the second surface BS2 of the base layer BSL).

In an embodiment, the printed circuit board PCB_1 may include a depression OP formed by etching at least a portion thereof. For example, the depression OP may be formed by etching at least a portion of the printed circuit board PCB_1 at a first point P1′ adjacent to a first end of the printed circuit board PCB_1.

For example, as illustrated in FIG. 11A, a portion of the printed circuit board PCB_1 may be partially etched at the first point P1′ adjacent to the first end of the printed circuit board PCB_1 so that a depression OP may be formed in the printed circuit board PCB_1 by a depth corresponding to about a half of the thickness of the printed circuit board PCB_1.

In an embodiment, the driving circuit RSIC_1 may be received (or disposed) in the depression OP of the printed circuit board PCB_1. In other words, the driving circuit RSIC_1 may be disposed between the printed circuit board PCB_1 and the connection film COF_1, and may be received (or disposed) in the depression OP of the printed circuit board PCB_1.

As such, because the driving circuit RSIC_1 is received (or disposed) in the depression OP of the printed circuit board PCB_1, the connection film COF_1 may remain planarized at the outside (or under a lower surface) of the display panel DP, and the overall thickness of the display device (e.g., the display device DD of FIG. 11) may be reduced.

The embodiment of the disclosure is not limited thereto. For example, as illustrated in FIG. 11B, a portion of a printed circuit board PCB_2 that corresponds to a first point P1′ adjacent to the first end of a printed circuit board PCB_2 (320_2) may be completely etched so that a depression OP_1 may be formed. The depression OP_1 formed at the first point P1′ may correspond an opening (or a hole) by which at least a portion of the printed circuit board PCB_2 is open. Because a driving circuit RSIC_2 (310_2) is received and disposed in the depression OP_1 formed by opening at least a portion of the printed circuit board PCB_2, the planarization of the connection film COF_2 (300_2) may be further improved, and the overall thickness of the display device (e.g., the display device DD of FIG. 1) may be further reduced.

Referring again to FIG. 11A, in an embodiment, the driving circuit RSIC_1 may be received (or disposed) in the depression OP of the printed circuit board PCB_1 and disposed between the printed circuit board PCB_1 and the connection film COF_1, so that the driving circuit RSIC_1 may at least partially overlap the depression OP of the printed circuit board PCB_1, in a plan view (e.g., based on a surface parallel to the second surface BS2).

For example, referring to FIG. 11C, the driving circuit RSIC_1 may be disposed to at least partially overlap the depression OP formed at the first point P1′ of the printed circuit board PCB in a plan view (e.g., based on a surface that is parallel to the second surface BS2 and is defined by the first direction DR1 and the second direction DR2).

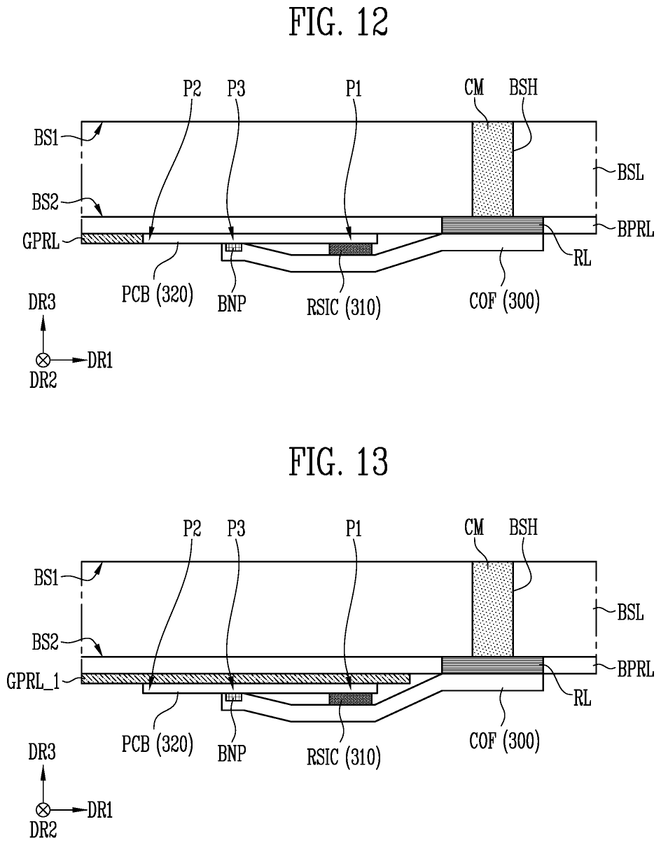

FIG. 12 is a schematic partial cross-sectional view of the display device in accordance with an embodiment of the disclosure.

To avoid redundant explanation, the following description with reference to FIG. 12 will be made, based on difference from the foregoing embodiments. Components which are not separately explained in the following description may comply with that of the foregoing embodiments. The same reference numeral will be used to designate the same component, and a similar reference numeral will be used to designate a similar component.

FIG. 12 illustrates a modification of the embodiment of FIG. 10A with an additional component (e.g., a second protective layer GPRL).

Referring to FIG. 12, the second protective layer GPRL (or a second lower protective layer) may be further disposed on a lower surface (e.g., a rear surface) of the first protective layer BPRL to cover at least a portion of the first protective layer BPRL. For example, the second protective layer GPRL and the printed circuit board PCB may be disposed on a same layer.

The second protective layer GPRL may dissipate heat generated from the display panel DP. For example, the second protective layer GPRL may include at least one of graphite, a carbon nanotube, and a heat pipe.

FIG. 13 is a schematic partial cross-sectional view of the display device in accordance with an embodiment of the disclosure.

To avoid redundant explanation, the following description with reference to FIG. 13 will be made, based on difference from the foregoing embodiments. Components which are not separately explained in the following description may comply with that of the foregoing embodiments. The same reference numeral will be used to designate the same component, and a similar reference numeral will be used to designate a similar component.

FIG. 13 illustrates a modification of the embodiment of FIG. 12 with regard to a second protective layer GPRL_1.

Referring to FIG. 13, the second protective layer GPRL_1 may be disposed between the base layer BSL (or the first protective layer BPRL) of the display panel DP and the printed circuit board PCB. Hence, heat generated from the driving circuit RSIC may be further blocked by the second protective layer GPRL_1, so that influence of the heat generated from the driving circuit RSIC on the light emitting element LD included in the display panel DP may be further minimized (or removed).

In a display device in accordance with an embodiment of the disclosure, a driving circuit may be disposed between a printed circuit board and a connection film. Hence, influence of heat generated from the driving circuit on a light emitting element included in a display panel may be minimized (e.g., removed), so that the reliability of the light emitting element can be enhanced.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a base layer including a first surface and a second surface;
a first line disposed on the first surface of the base layer;
a second line corresponding to the first line and disposed on the second surface of the base layer; and
a connection film electrically contacting at least a portion of the second line and electrically connected to a printed circuit board and a driving circuit,
wherein the driving circuit is disposed between the printed circuit board and the connection film.

2. The display device according to claim 1, wherein the printed circuit board and the connection film electrically contact each other on a first point between a second point corresponding to a first end of the printed circuit board and a third point corresponding to a second end of the printed circuit board.

3. The display device according to claim 2, wherein the printed circuit board and the connection film are electrically connected to each other by a bonding pad including a pad electrode.

4. The display device according to claim 2, wherein the driving circuit is located at the second point.

5. The display device according to claim 1, wherein the driving circuit at least partially overlaps the printed circuit board in a plan view.

6. The display device according to claim 2, wherein the printed circuit board includes a depression formed by etching at least a portion of the printed circuit board.

7. The display device according to claim 6, wherein the driving circuit is disposed in the depression of the printed circuit board.

8. The display device according to claim 6, wherein the depression of the printed circuit board is located at the second point.

9. The display device according to claim 6, wherein the driving circuit at least partially overlaps the depression of the printed circuit board in a plan view.

10. The display device according to claim 1, further comprising:
a first protective layer disposed on an entire area of the second surface including the second line and including an area exposing at least a portion of the second line.

11. The display device according to claim 10, further comprising:
a second protective layer disposed on a lower surface of the first protective layer to cover at least a portion of the first protective layer.

12. The display device according to claim 11, wherein the second protective layer and the printed circuit board are disposed on a same layer.

13. The display device according to claim 11, wherein the second protective layer is disposed between the first protective layer and the printed circuit board.

14. The display device according to claim 11, wherein the second protective layer includes graphite.

15. The display device according to claim 1, further comprising:
a pixel circuit layer disposed on the first surface of the base layer and including the first line;
a display element layer disposed on the pixel circuit layer and including a display element; and
a thin-film encapsulation layer disposed on the display element layer.

16. The display device according to claim 15, further comprising:
a light conversion layer disposed between the display element layer and the thin-film encapsulation layer.

17. The display device according to claim 15, wherein
the pixel circuit layer comprises at least one transistor and a plurality of insulating layers,
the at least one transistor comprises:
a semiconductor pattern disposed on the first surface of the base layer and including a channel area, a source area, and a drain area;
a gate electrode disposed to overlap the channel area in a plan view; and
a source electrode and a drain electrode respectively electrically connected to the source area and the drain area, and
the plurality of insulating layer comprises:
a gate insulating layer disposed between the semiconductor pattern and the gate electrode; and
an interlayer insulating layer disposed on the gate electrode.

18. The display device according to claim 17, wherein
the first line includes at least one of a first gate line and a first data line,
the second line includes at least one of a second gate line electrically connected to the first gate line through a base hole passing through the base layer and a second data line electrically connected to the first data line through the base hole,
the first gate line and the gate electrode are disposed on a same layer, and
the first data line and at least one of the source electrode and the drain electrode are disposed on a same layer.

19. The display device according to claim 18, wherein
the base hole is filled with a conductive material, and
the first line and the second line are electrically connected to each other by the conductive material.

20. A display device comprising:
a base layer including a first surface and a second surface;
a first line disposed on the first surface of the base layer;
a second line corresponding to the first line and disposed on the second surface of the base layer; and
a connection film electrically contacting at least a portion of the second line and electrically connected to a printed circuit board and a driving circuit,
wherein the driving circuit at least partially overlaps the printed circuit board in a plan view.
